(19) United States
(12) Patent Application Publication
(10) Pub. No.: US 2014/0308814 A1
(43) Pub. Date: Oct. 16, 2014

(54) CHEMICAL MECHANICAL POLISHING METHODS AND SYSTEMS INCLUDING PRE-TREATMENT PHASE AND PRE-TREATMENT COMPOSITIONS

(71) Applicant: Applied Materials, Inc, Santa Clara, CA (US)

(72) Inventors: David Maxwell Gage, San Jose, CA (US); You Wang, San Jose, CA (US); Zhihong Wang, Sunnyvale, CA (US); Wen-chiang Tu, Fremont, CA (US)

(73) Assignee: Applied Materials, Inc, Santa Clara, CA (US)

(21) Appl. No.: 13/862,920

(22) Filed: Apr. 15, 2013

(51) Int. Cl. H01L 21/306; C09G 1/04; H01L 21/67

(52) U.S. Cl. CPC H01L 21/30625; H01L 21/67075; C09G 1/04
USPC 438/693; 252/79.1; 156/345.12

(57) ABSTRACT

In one aspect, a substrate chemical mechanical polishing (CMP) method for copper-layered substrates is disclosed. The CMP method includes providing a substrate having a surface of copper, and pre-treating the surface containing copper with a first composition containing a carrier liquid, a corrosion inhibitor, and an oxidizer in a pre-treatment phase, and thereafter, polishing the surface with a slurry composition in a main polishing phase. CMP systems and compositions for CMP are provided, as are numerous other aspects.

### FIELD

The present invention relates generally to semiconductor device manufacturing, and more particularly to chemical mechanical polishing.

### BACKGROUND

Within semiconductor substrate manufacturing, a planarization process may be used to remove various layers or films, such as silicon dioxide, silicon nitride, copper, or the like from a substrate (e.g., a patterned wafer). Planarization may be accomplished using a chemical mechanical polishing (CMP) process by instituting an abrasive slurry between a polishing pad and the substrate surface to be polished (e.g., planarized). The substrate is received in a substrate holder that applies pressure to force the substrate against the polishing pad. Both the substrate holder and the polishing pad may be rotated to facilitate the material removal. Further, the holder may oscillate the substrate back and forth across the surface of the polishing pad.

During certain planarization processes, although sufficient material removal may be accomplished with existing processes and slurries, improvements in planarization efficiency are sought after so as to reduce process cost. Accordingly, improved polishing methods are sought.

### SUMMARY

In a first aspect, a chemical mechanical polishing pretreatment method is provided. The chemical mechanical polishing pretreatment method includes providing the substrate having a surface containing copper, pre-treating the surface containing copper with a first composition comprising carrier liquid, a corrosion inhibitor, and an oxidizer to form a passivation layer, and thereafter, polishing the surface with a second composition comprising a slurry.

In another aspect, a chemical mechanical polishing system is provided. The chemical mechanical polishing system includes a substrate held in a substrate holder, the substrate having a surface containing copper, a polishing pad, a distributor operable to dispense a first chemical solution between the substrate and the polishing pad as a pre-treatment phase to a polishing phase introducing a slurry.

In yet another aspect, a composition adapted to chemical mechanical polishing of a substrate is provided. The composition includes a carrier liquid in an amount between about 97.2% and about 98.8%, a corrosion inhibitor in an amount between about 0.05% and about 0.30%, and an oxidizer between about 0.2% and about 2.0%.

Other features and aspects of the present invention will become more fully apparent from the following detailed description of example embodiments, the appended claims, and the accompanying drawings.

### BRIEF DESCRIPTION OF THE DRAWINGS

FIG. 1 illustrates a partial side plan of a chemical mechanical polishing system according to embodiments.

FIG. 2 illustrates cross-sectioned partial side view of a substrate at an incoming stage before being polished according to embodiments.

FIG. 3 illustrates cross-sectioned partial side view of a substrate after a pre-treatment phase according to embodiments.

FIG. 4 illustrates cross-sectioned partial side view of a substrate after partial planarization during a main polishing phase according to embodiments.

FIG. 5 illustrates cross-sectioned partial side view of a substrate after completing a planar surface during the main polishing phase according to embodiments.

FIG. 6 illustrates a plot of pattern step height versus amount of copper removed according to embodiments.

FIG. 7 illustrates a flowchart of a chemical mechanical polishing method according to embodiments.

### DETAILED DESCRIPTION

Embodiments described herein relate to systems, slurries, and methods adapted to polish a surface of a substrate containing a copper layer. In particular, chemical mechanical polishing methods and compositions adapted to provide improved copper layer planarization are provided. The methods and compositions are used to improve planarization efficiencies when polishing copper layer formed on a silicon-containing substrate.

In accordance with one or more embodiments, the improved method involves instituting a pre-planarization phase wherein a passivation layer is formed on the copper layer before the main planarization phase takes place wherein material removal takes place in the main planarization phase (i.e., using abrasives on the deposited copper layer). The pre-planarization phase where a passivation layer is formed is carried out using the same polishing pad as used for the planarization phase. The pre-planarization phase involves exposing the copper layer on the substrate to a first chemical solution by applying the first chemical solution to the polishing pad for a sufficient time and under sufficient pressure to form a thin passivation layer (e.g., a CuO or Cu₂O) on the surface of the copper layer. The up areas of the copper layer are rapidly removed via combinations of the abrasives and the etchants in the CMP slurry, while the down areas are protected by the passivation layer to inhibit material removal by etching components of the slurry. Overall etching efficiency may be increased by utilization of the pre-planarization phase.

CMP pre-planarization chemical compositions are provided, as are other aspects.

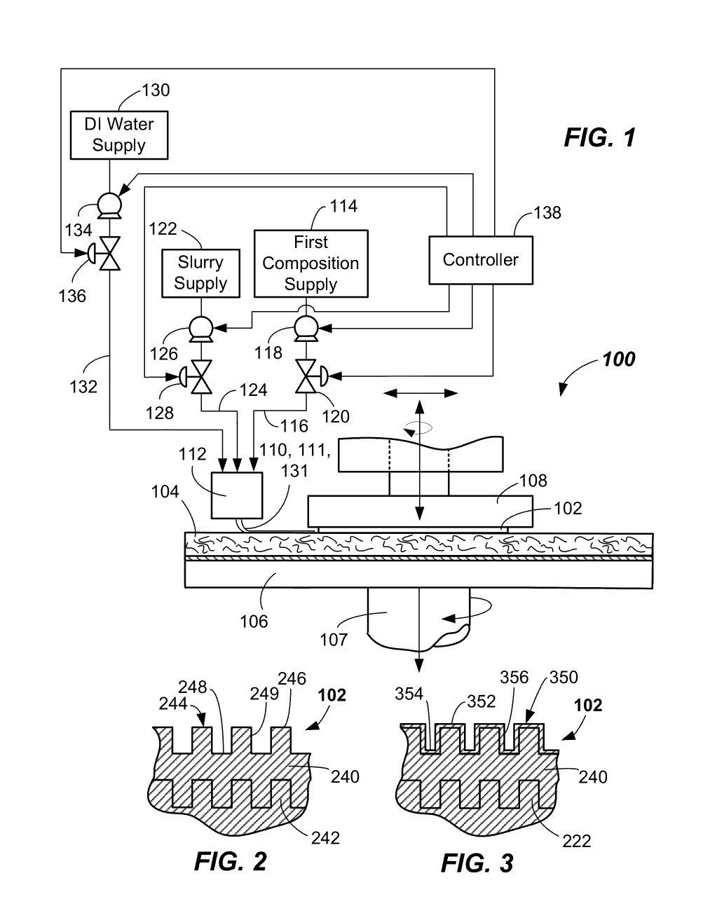

These and other aspects of embodiments of the invention are described below with reference to FIGS. 1-7 herein.

FIG. 1 illustrates a partial side view of a chemical mechanical polishing (CMP) system 100 and components thereof. The CMP system 100 is adapted to hold a substrate 102 in relationship to a polishing pad 104, and is used to carry out a pre-treatment and polishing process in accordance with another aspect of the invention. The substrate 102 may be a wafer, such as a patterned wafer including partially-formed transistors or patterns formed thereon. The substrate 102 may include a silicon-containing base having a copper-containing layer deposited thereon. The copper layer may have been previously deposited onto the silicon surface such as by a deposition process.

The polishing pad 104 may be of conventional construction, and may comprise any suitable porous material such as a rigid micro-porous polyurethane pad. The polishing pad 104 may be mounted (e.g., adhered) onto a conventional platen 106 that may be rotated by a suitable motor (not shown) coupled to the platen 106 by shaft 107. Polishing pad 104 may have a shore D hardness per ASTM D2240 of between about 30 and about 70, and between about 52 and about 62 in some embodiments. The polishing pad 104 may have a pore size between about 30 and about 70 microns, and a porosity of between about 10% and 50%, for example. Other hardness, pore sizes, and porosities may be used.

Disc-shaped platen 106 may be rotated at between about 10-200 RPM, between about 20 RPM and about 120 RPM, and between about 50 RPM and about 100 RPM in some embodiments, for both the pre-treatment phase and the main polishing phase. Other rotational speeds may be used. Pre-treatment phase shall refer to a phase before polishing where a passivation layer is formed, whereas the main polishing phase shall refer to a material-removal phase wherein the copper layer is planarized by using a slurry containing an abrasive and possibly an etchant.

The substrate 102 may be held in a substrate holder 108 of conventional construction. Substrate holders (also referred to as retainers or carrier heads) are described in U.S. Pat. No. 8,298,047; U.S. Pat. No. 8,088,299; U.S. Pat. No. 7,883,397; and U.S. Pat. No. 7,459,057, issued to the present assignee, for example. Other types of substrate holders may be used. Substrate holder 108 may be rotated and may also be scanned (e.g., oscillated) back and forth across the surface of the polishing pad 104 as the polishing pad 104 is being rotated in contact with the substrate 102. The holder oscillation rate may between about 0.1 mm/s and 5 mm/s. for example. Other oscillation rates may be used. Substrate holder 108 may be rotated at between about 10 RPM to about 200 RPM.

During the pre-treatment phase, a pressure may be applied to the substrate 102 pressing it onto the pad 104. The pressure applied during the pre-treatment phase may be less than a pressure applied during the main polishing phase. For example, the pressure applied during the pre-treatment phase may between about 0.5 psi and about 2.0 psi, or even between about 0.5 psi and about 1.5 psi, in some embodiments, for example. The pressure during the main polishing phase may be between about 1.0 psi and about 3.0 psi, for example. Other rotational speeds and applied pressures may be used. The scanning back and forth may take place between a center and a radial side of the polishing pad 104.

At the start of the pre-treatment phase, a first composition 110 is provided onto the polishing pad 104. The first composition 110 may be instituted and inserted between the polishing pad 104 and the substrate 102 by a distributor 112. Distributor 112 may be any suitable dispensing head or device adapted to dispense the first composition 110 onto the pad 104. The distributor 112 may have a plurality of openings to dispense the first composition 110, and may be operable to evenly dispense the first composition 110 onto the polishing pad 104. The distributor 112 may be coupled to a dispensing arm in some embodiments, and may be oscillatory thereon.

Prior to the pre-treatment phase, a rinse of the polishing pad 104 may be accomplished, such as by providing DI water to the polishing pad 104. Pad conditioning may be provided as well, as will be described herein. Distributor 112 may be fluidly coupled to a first composition supply 114, such as by one or more suitable conduits 116. Flow may be controlled by suitable pump 118 and/or valves 120 or other liquid conveying or transfer mechanism(s) to supply a metered amount of the first composition 110 to the surface of the polishing pad 104. In the depicted embodiment, the first composition 110 may be dispensed onto the surface of the polishing pad 104 ahead of the substrate 102 by the distributor 112 so that the first composition 110 is received in front of the substrate 102 and is drawn between the polishing pad 104 and the substrate 102 by the rotation of the polishing pad 104.

The chemical composition of the first composition 110 may be any suitable composition adapted to form a passivation layer on the copper surfaces of the substrate 102 upon exposure thereto. The passivation layer may operate to protect certain lower portions (e.g., bottom portions 248, side portions 249) of the surface (to be described herein) of the substrate 102 when a second composition comprising an abrasive-containing slurry 111 is applied to the polishing pad 104 during a main polishing phase, as is described more fully below.

The first composition 110, in one or more embodiments, may include de-ionized water (DI water), a corrosion inhibiter, and an oxidizer. In some embodiments, the first composition 110 may also include a pH adjuster. In one or more embodiments, the first composition 110 may be devoid of an abrasive, whereas the later applied second composition comprising a slurry 111 may contain a suitable abrasive. The corrosion inhibiter may be Benzotriazole, 1,2,4-Triazole, or the like. Oxidizer may be hydrogen peroxide (H₂O₂), or the like.

In one or more embodiments, the first composition 110 may contain between about 97.2% and about 98.8% of a liquid carrier, such as DI water. Other suitable carrier liquids may be used. Another suitable first composition 110 may include between about 97.2% and about 98.8% of a carrier liquid such as DI water, between about 0.05% and about 0.30% of the corrosion inhibitor, and between about 0.2% and about 2.0% of the oxidizer.

Another suitable composition for the first composition 110 that may be applied proceeding the introduction of the slurry 111 is a composition containing between about 97.2% and about 98.8% of a carrier liquid such as DI water, between about 0.05% and about 0.30% Benzotriazole as the corrosion inhibitor, between about 0.2% and about 2.0% of H₂O₂ as the oxidizer, and a pH adjuster. The pH adjuster may be NH₄OH provided in between about 0.05% and about 0.5%. The pH adjuster operates to adjust the pH of the first composition 110 so that the pH may fall within the range of about 7.5 pH and about 9.5 pH. Other pH adjusters may be used. For example, hydroxide or other source of hydroxyl ions such as Potassium hydroxide, hydrogen peroxide, or the like, may be provided in an effective amount.

The dispensing of the first composition 110 onto the polishing pad 104 during the pre-treatment phase may occur for between about 5 seconds and about 30 seconds, and about 20 seconds in some embodiments. The flow rate of the first solution 110 onto a polishing pad 104 may be between about 50 mL/min and about 500 mL/min, and about 300 mL/min in some embodiments. Other flow rates and pre-treatment times may be used.

In the main polishing phase, following the pre-treatment phase, a slurry 111 containing an abrasive may be provided from a slurry supply 122 and delivered through conduit 124 to the distributor 112. Flow control may be provided by valve 128 and/or pump 126 to cause a metered supply of the second composition comprising a slurry 111 containing abrasives to instituted and inserted between the polishing pad 104 and the substrate 102. Other liquid conveying or transfer mechanisms may be used. The slurry 111 may be dispensed by the distributor 112 and be used in the polishing process. The slurry 111 may be used, in particular, to remove bulk copper from the substrate 102 that has been previously applied.

In the depicted embodiment, the slurry 111 may be dispensed onto the surface of the polishing pad 104 ahead of the substrate 102 by the distributor 112 so that the slurry 111 is received in front of the substrate 102 and is drawn between the polishing pad 104 and the substrate 102 by the rotation of the pad 104 and is used to facilitate the polishing process. In the depicted embodiment, the slurry 111 contains an abrasive, such as silica particles or the like. Other suitable abrasives may be used. Slurry 111 may also include a chelating and/or a complexing agent. The slurry 111 may have up to about 0.6 wt % of a complexing agent, such as Glycine.

Slurry 111 may also include a corrosion inhibitor, such as 1,2,4-Triazole, or the like. In some embodiments, the abrasive slurry 111 contains silica particles, 1,2,4-Triazole, and 1,2-Ethanediol. Slurry 111 may have a pH of between about 6.0 pH and about 8.0 pH, for example. Hydroxide or other source of hydroxyl ions may be added in an effective amount to bring about suitably basic conditions. Other additives may be included. As should be apparent, the first composition 110 that is adapted to form a thin passivation layer may be a non-abrasive composition, whereas the second composition may be an abrasive-containing slurry 111.

Accordingly, the CMP system 100 is useful for pretreating a copper surface of the substrate 102 to form a passivation layer thereon, followed by polishing a surface of a substrate 102 with an abrasive slurry 111 to remove copper material and provide a planar surface thereon.

After each of the pre-treatment and polishing phases is completed, a rinse liquid may be used to finish the processing. The rinse liquid 131 may be a DI water rinse, and may be instituted during and/or after wafer de-chuck. The wafer de-chuck refers to where the substrate 102 (e.g., wafer) and the substrate holder 108 are lifted from the surface of the polishing pad 104 after processing on the platen 106 is completed, such that the substrate 102 is no longer in contact with the pad surface. The purpose of the rinse is not only to clean the polishing pad 104, but possibly also to clean the substrate 102 to some degree. Additionally, before the next substrate 102 is mounted in the substrate holder 102, there may be a pad conditioning phase, in which a conventional pad conditioning disk is swept across the pad 104 with some applied down force in the presence of DIW rinse to roughen and further clean the surface of the polishing pad 104. In one embodiment, the DI water rinse may be provided from a DI Water Supply 130 and flow of the rinse liquid 131 may be controlled through rinse conduit 132 by pump 134 and/or valve 136. DI water supply 130 may supply rinse water 131 to be dispensed from the same distributor 112 that dispenses the first composition 110 and second composition 111 (slurry), or the DI rinse water 131 may be dispensed from a separate set of nozzles that are coupled to a dispenser arm. Control of the flows to the distributor 112 may be by control signals to pumps 118, 126, 134 and valves by a controller 138.

In accordance with another embodiment of the invention, as shown in FIGS. 2-5, several partial cross-sectional views of a substrate 102 at various stages in the CMP method are provided. FIG. 2 illustrates the substrate 102, in an incoming condition after undergoing a copper deposition process, wherein a copper layer 240 is provided over a base 242. “Base” as used herein may include a single pattered layer, a plurality of layers, or a base material. The surface 244 of the copper layer 240 that has been applied to the base 242 includes a pseudo pattern, generally following the contours of the underlying pattern on the base 242. Base 242 may be a silicon-containing material having a pattern etched or otherwise provided thereon. The surface 244 of the copper layer 240 includes upper portions 246 and lower portions, such as bottoms 248 and sides 249.

FIG. 3 illustrates another stage in the CMP method. FIG. 3 illustrates the substrate 102, after being mounted in the substrate holder 108 and being subjected to the pre-treatment phase. During the pre-treatment phase, a passivation layer 350 is formed over the copper layer 240. Exposure of the copper layer 244 to the first composition 110 as mounted in the substrate holder 108 formed the passivation layer 350. The pre-treating forms the passivation layer 350, which may have a layer thickness less than about 3 nm, for example. Other thicknesses may be formed. The layer 350 includes upper layer regions 352 covering the upper portions 246 and lower layer regions including bottom layer regions 354 covering bottom portion 248 and side layer regions 356 covering side portions 249.

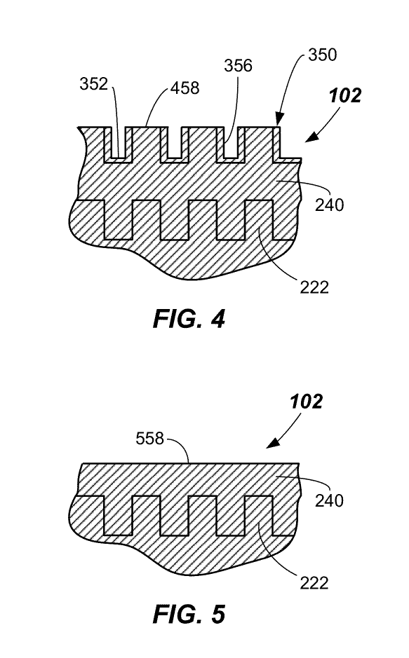

As is shown in FIG. 4, the substrate 102, having undergone the pre-treatment phase may then undergo the main polishing phase, where the slurry 111 is provided onto the polishing pad 104 and the material removal begins. As shown in FIG. 4, the slurry 111 is instituted between the substrate 102 and the polishing pad 104 and the upper layer region 352 and the upper portions 246 are removed. During this polishing phase, the lower portions comprising the bottom portions 246 and the side portions 248 continue to be covered by the passivation layer 350 and are protected thereby.

As shown in FIG. 5, the main polishing phase continues with the slurry 111 comprising an abrasive being applied to the polishing pad 104 and the substrate 102 in contact with the moving pad 104. The main polishing phase continues until the top contours (e.g., the top portions 246, side portions 249, and passivation layer 350) are all removed, and a planar surface 558 is provided on the copper layer 240 as shown in FIG. 5. After polishing is completed, the planar surface 558 may have a root mean squared (RMS) roughness value of the copper surface of less than about 1 nm (post-CMP). Other RMS roughness values may be provided, depending on other factors, such as the quality of the deposited Cu layer. Surface roughness characterization in RMS may be reported in terms of root mean square (RMS) surface roughness as measured by atomic force microscopy or some other surface measurement technique.

All percentages used herein are weight percentages per the relationship:

Weight%=(component weight/total slurry weight)×100%

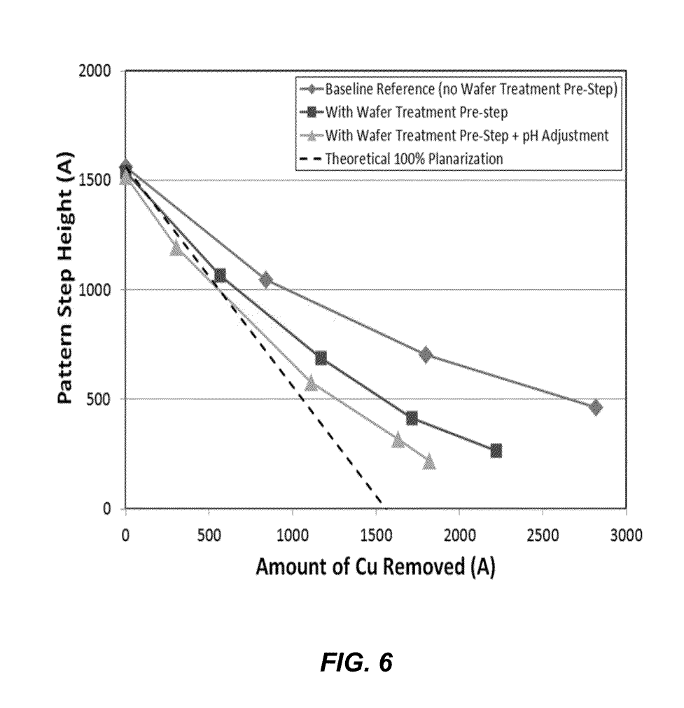

FIG. 6 illustrates a plot of pattern step height versus amount of copper removed illustrating one possible advantage of embodiments of the invention. In particular, a CMP process including a pre-treatment phase wherein the substrate 102 is exposed to a first composition 110 before a main polishing phase offers improved planarization efficiency from <40% to >60%, as compared to a baseline performance for polishing with a process of record (POR) Cu slurry alone. Optional pH adjustment may offer further efficiency improvements.

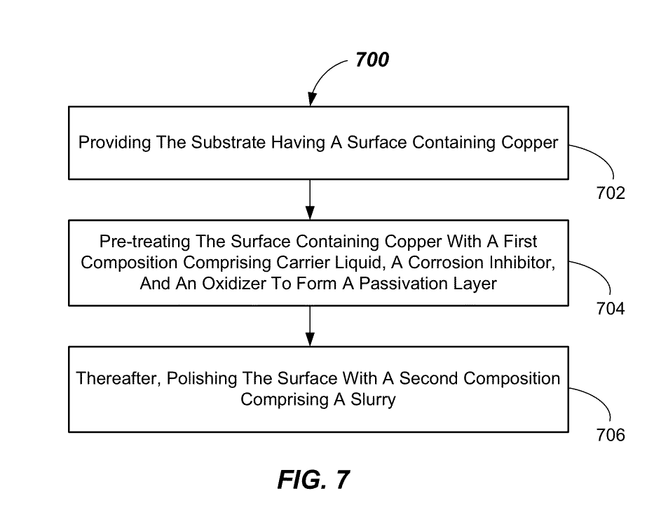

FIG. 7 illustrates a chemical mechanical polishing method 700 adapted to process a substrate (e.g., substrate 102), and in particular a method of polishing a substrate (e.g., substrate 102) having a copper layer (e.g., copper layer 240) to provide a planar surface (e.g., planar surface 558 thereon).

The method 700 includes, in 702, first providing a substrate (e.g., substrate 102) having a surface containing copper (e.g., a copper layer 240), and, in 704, pre-treating the surface containing copper with a first composition (e.g., first composition 110) comprising carrier liquid (e.g., DI water), a corrosion inhibitor (e.g., Benzotriazole), and an oxidizer (e.g., H₂O₂) to form a passivation layer (e.g., passivation layer 350). Pre-treating the surface may be provided in a pre-treatment phase of the CMP method. Thereafter, the method 700 includes polishing the surface with a second composition (e.g., second composition 111) comprising a slurry. The polishing may take place in a main polishing phase taking place directly after the pre-treating the surface in the pre-treatment phase of the CMP method. The polishing phase includes using an abrasive to remove copper material.

Accordingly, while the present invention has been disclosed in connection with example embodiments thereof, it should be understood that other embodiments may fall within the scope of the invention, as defined by the following claims.

The invention claimed is:

1. A chemical mechanical processing system, comprising:
a substrate held in a substrate holder, the substrate having a surface containing copper;
a polishing pad; and
a distributor operable to dispense a first chemical solution between the substrate and the polishing pad as a pre-treatment phase to a polishing phase introducing a slurry.

2. The chemical mechanical polishing system of claim 1, wherein the first composition is supplied to the distributor in the pre-treatment phase prior to introduction of the slurry from a slurry supply.

3. The chemical mechanical polishing system of claim 1, comprising a first composition supply and a slurry supply coupled to the distributor wherein the first composition supply and the slurry supply are separate.

4. The chemical mechanical polishing system of claim 1, wherein the first composition comprises DI water, a corrosion inhibiter, and an oxidizer.

5. The chemical mechanical polishing system of claim 4, further comprising a pH adjuster.

6. The chemical mechanical polishing system of claim 4, wherein the first composition is devoid of an abrasive.

7. The chemical mechanical polishing system of claim 4, wherein the first composition comprises between about 97.2% and about 98.8% DI water.

8. The chemical mechanical polishing system of claim 4, wherein the first composition comprises:
between about 97.2% and about 98.8% of the DI water, between about 0.05% and about 0.30% of the corrosion inhibitor, and
between about 0.2% and about 2.0% of the oxidizer.

9. The chemical mechanical polishing system of claim 4, wherein the first composition comprises:
between about 97.2% and about 98.8% of the DI water;
between about 0.05% and about 0.30% Benzotriazole as the corrosion inhibitor;
between about 0.2% and about 2.0% of H₂O₂ as the oxidizer; and
between about 0.05% and about 0.5% of NH₄OH as a PH adjuster.

10. A substrate processing method, comprising:
providing the substrate having a surface containing copper;
pre-treating the surface containing copper with a first composition comprising carrier liquid, a corrosion inhibitor, and an oxidizer to form a passivation layer; and
thereafter, polishing the surface with a second composition comprising a slurry.

11. The method of claim 10, wherein the passivation layer having a thickness less than about 3 nm.

12. The method of claim 10, wherein the pre-treating the surface containing copper comprises:
dispensing the first solution onto a polishing pad, and
inserting the first solution between the polishing pad and the substrate.

13. The method of claim 12, wherein the dispensing the first solution onto a polishing pad occurs for between about 5 seconds and about 30 seconds.

14. The method of claim 12, wherein the flow rate of the first solution onto a polishing pad is between about 50 mL/min and about 500 mL/min.

15. The method of claim 12, wherein the first composition further comprises a pH adjuster.

16. The method of claim 12, wherein the first composition is devoid of an abrasive.

17. The method of claim 12, wherein the first composition further comprises:
between about 97.2% and about 98.8% of the DI water;
between about 0.05% and about 0.30% of the corrosion inhibitor; and
between about 0.2% and about 2.0% of the oxidizer.

18. The method of claim 12, wherein the first composition further comprises:
between about 97.2% and about 98.8% of the DI water;
between about 0.05% and about 0.30% Benzotriazole as the corrosion inhibitor;
between about 0.2% and about 2.0% of H₂O₂ as the oxidizer; and
between about 0.05% and about 0.5% of NH₄OH as a PH adjuster.

19. A composition adapted to chemical mechanical polishing of a substrate, comprising:
a carrier liquid in an amount between about 97.2% and about 98.8%;
a corrosion inhibitor in an amount between about 0.05% and about 0.30%; and
an oxidizer between about 0.2% and about 2.0%.

20. The composition of claim 19, comprising:
Benzotriazole as the corrosion inhibitor; and
H₂O₂ as the oxidizer.
